(19) United States
(12) Patent Application Publication
(10) Pub. No.: US 2005/0003659 A1
(43) Pub. Date: Jan. 6, 2005

(54) Transparent inter-metal dielectric stack for CMOS image sensors

(75) Inventors: Leah Markowitz, Givat Ela (IL); Roey Shaviv, Givat Ela (IL)

Correspondence Address: BEVER HOFFMAN & HARMS, LLP;TRI-VALLEY OFFICE, 1432 CONCANNON BLVD., BLDG. G, LIVERMORE, CA, 94550, US

(73) Assignee: Tower Semiconductor Ltd.

(21) Appl. No.: 10/613,849

(22) Filed: Jul. 3, 2003

(51) Int. Cl. H01L 21/4763

(52) U.S. Cl. 438/641

(57) ABSTRACT

A transparent inter-metal dielectric utilized in a CMOS image sensor includes a flowlayer sandwiched between a base SiO₂ layer and a cap SiO₂ layer. The flowlayer is formed by reacting SiH₄ and H₂O₂ using a shortened H₂O₂ stabilization time, using a reduced deposition pressure, and while maintaining the reaction chamber platen at a target value of approximately 1° C.

### FIELD OF THE INVENTION

The present invention relates to the fabrication of ultra large-scale integrated circuits (ICs) and, more particularly, to an improved method for forming an inter-metal dielectric stack during the fabrication of an image sensor.

### BACKGROUND OF THE INVENTION

Solid-state image sensors are used, for example, in video cameras, and are presently realized in a number of forms including charge-coupled devices (CCDs) and complementary metal-oxide-silicon (CMOS) image sensors. These image sensors are based on a two dimensional array of pixels, with each pixel including a photodetector device (light sensing element) and associated access circuitry. Each photodetector device is capable of converting a portion of the visible light image into an electronic signal representing that image portion. The electronic signals from all of the photodetector devices collected at a selected time are collectively referred to as a frame, which provides an electrical signal representative of the image suitable for computerized storage, analysis, processing, and comparison.

Recently, image sensors have been undergoing a transition from a multi-chip arrangement, in which the image sensor and signal processing circuitry are formed on separate chips that are connected together using a printed circuitry board, to a “camera on chip” concept in which signal processing circuitry and image sensing circuitry are fabricated on the same substrate.

FIG. 1 is a simplified block diagram showing a CMOS image sensor 100 that is fabricated according to the “camera on chip” concept. CMOS image sensor 100 generally includes a color pixel array 110, a logic circuit 120, and several contact pads 130. Pixel array 110 includes an array of pixels formed on a substrate, and a color filter array formed over the pixel array. Each pixel of the pixel array includes a photodiode (or other light sensing element) and associated control circuitry. The color filter array includes red (R), green (G), and blue (B) color filter “tiles” arranged in a predetermined pattern such that each tile is located over a corresponding pixel of the pixel array. During operation, the pixels are accessed (i.e., read) by logic circuit 120, which processes signals generated by the pixels in response to incident light. Image data generated by logic circuit 120 is then passed out of CMOS image sensor 120 via contact pads 130 according to known techniques.

FIG. 2 is a simplified cross-sectional side view showing CMOS image sensor 100 in additional detail. Pixel circuit structures 210 and logic circuit structures 215 are formed on a semiconductor (e.g., silicon) substrate 201 according to known techniques. These structures are connected by metal vias to a series of metal structures that facilitate communication between pixel array 210 and logic circuit 220. The metal structures shown in FIG. 2 are identified by the metal layer (i.e., metal-layer 1 or M1, metal-layer 2 or M2, and metal-layer 3 or M3) from which these structures are etched according to known techniques. Each of the metal layers is formed on a dielectric layer that serves to insulate the metal structures from each other. For example, structures of metal layer M1 are formed on a lower dielectric layer 220 (e.g., Boron Phosphorous Silicated Glass (BPSG)), structures of metal layer M2 are formed on a first inter-metal dielectric layer 230 (i.e., inter-metal layer 230 is formed between the structures of metal layers M1 and M2), and structures of metal layer M3 are formed on a second inter-metal dielectric layer 240 (i.e., inter-metal layer 240 is formed between the structures of metal layers M2 and M3). A passivation layer 250 is formed over the structures of third metal layer M3. A color filter array 260 is formed over passivation layer 250, and includes a lower transparent layer 262, a plurality of color tiles 264, and an upper transparent layer 266. Optional microlens structures 268 are formed over (or, in some cases, under) color filter array 260 to focus light through underlying color filter tiles to the underlying associated pixel. An upper protective layer 270 (e.g., a polymer material) is formed over color filter array 260, and finally contact pads 130 (shown in FIG. 1) are formed on upper protective layer 270. Note that contact pads 130 connect to the underlying logic circuitry by vias (not shown).

In order for the structure shown in FIG. 2 to operate as an image sensor, the dielectric, passivation and protective layers formed over the light detecting regions of pixel circuits 210 must be light transparent in order to pass light through these layers to the light detecting regions of the underlying pixels. As such, inter-metal dielectric layers 230 and 240, and passivation layer 250 play a paramount role in the functionality of “camera on chip” image sensors. That is, in order to support the large number of signal routing lines needed to communicate between the pixels and the logic circuitry, several metal layers (e.g., metal layers M1, M2, and M3) are required. Because each of these metal layers must be separated by an inter-metal dielectric layer, each inter-metal dielectric layer must be transparent and highly planarized to avoid scattering light passing through these layers to the light detecting regions of the underlying pixels.

FIG. 3 is a cross sectional view showing a conventional inter-metal dielectric structure 300 (referred to herein as a dielectric “stack”) that is disclosed in co-owned U.S. Pat. No. 5,891,800, which is incorporated herein by reference in its entirety. As indicated, inter-metal dielectric stack 300 may be utilized to form inter-metal dielectric layers 230 and 240, and in some instances passivation layer 250, and includes a base layer 310, a first flowlayer 320, a first cap layer 330, a second flowlayer 340, and a second cap layer 350. Base layer 310 includes SiO₂ that is deposited by plasma enhanced chemical vapor deposition (PECVD). First flowlayer 320 is then formed on base layer 310 by reacting SiH₄ (Silane gas) and H₂O₂ (peroxide) at 0° C. to form a liquid layer, believed to be primarily Si(OH)₄ in composition. The liquid flows around and above metal structures M, providing a substantially flat top surface. First capping layer 330 is then formed over first flowlayer 320, and includes SiO₂ that is deposited by PECVD. Second flowlayer 340 is then formed on first capping layer 330 in the manner used to form first flowlayer 320, and then second capping layer 350 is formed over second flowlayer 340 in the manner used to form first capping layer 330. According to the process described in U.S. Pat. No. 5,891,800, the wafer is warmed between the deposition of first cap layer 330 and the deposition of second flowlayer 340 to evaporate water from first flowlayer 320, and a similar warming process is used to evaporate water from second flowlayer 340. In addition, after the depositions of each flowlayer, the flowlayers are planarized by flowing H₂O₂ thereupon. The resulting inter-metal dielectric structure provides a relatively planarized transparent structure that can be utilized in the fabrication of CMOS image sensors.

A problem that has been attributed to conventional dielectric fabrication techniques is that CMOS image sensors formed by these methods exhibit a “rain drops” phenomenon (i.e., white spots) on images (pictures) that are generated by these image sensors.

The present inventors determined that the occurrence of the “rain drop” phenomenon described above result from the non-optimal conventional processing conditions used to produce inter-metal dielectric stack 300. In particular, visual inspection of a CMOS image sensor including inter-metal dielectric stacks 300 was performed using a bright light source and microscope objective at 45 degrees inclined to the wafer. Under these visual inspection conditions, different light intensity areas, referred to herein as spots, were observed in the dielectric stacks 300. The present inventors believe that these spots act like microlenses focusing and defocusing the light due to the longer path length when viewed off-axis, which produces the “rain drops” phenomenon in visual images generated by CMOS image sensors having these spots. This “rain drops” phenomenon rendered these CMOS image sensors dysfunctional for many uses.

What is needed is an improved method for producing image sensors that avoids the “rain drops” phenomenon described above. In particular, what is needed is a method for producing inter-metal dielectrics that are free from spots, thereby producing CMOS image sensors that are free from the “rain drops” phenomenon.

### SUMMARY OF THE INVENTION

The present invention is directed to method to deposit an improved, spot-free inter-metal dielectric stack for CMOS image sensors that eliminates the “rain drops” phenomenon associated with conventionally produced inter-metal dielectric stack. The method includes forming a base SiO₂ layer, forming a flowlayer on the base SiO₂ layer by reacting SiH₄ and H₂O₂, and forming a cap SiO₂ layer on the flowlayer. In accordance with a first aspect of the present invention, formation of the flowlayer is characterized by a modified H₂O₂ stabilization period that is substantially shorter (i.e., 30 to approximately 50 seconds) than that used in conventional methods. In accordance with a second aspect of the present invention, formation of the flowlayer is characterized by a modified deposition pressure that is substantially lower (i.e., 400 to approximately 600 mTorr) than that used in conventional methods. In accordance with a third aspect of the present invention, formation of the flowlayer is characterized by a modified platen temperature that is higher (i.e., 1 to 3 degrees Celsius) than that used in conventional methods. By utilizing one or more of these modifications during the formation of the flowlayer, an inter-metal dielectric is formed having a substantially lower occurrence of spots, thereby producing image sensors that are free of the raindrops phenomenon.

In accordance with a second embodiment of the present invention, a second flowlayer is formed over the first capping layer, with the second flowlayer being formed according to one or more of the aspects described above. A second SiO₂ cap layer is then formed over the second flowlayer.

### BRIEF DESCRIPTION OF THE DRAWINGS

These and other features, aspects and advantages of the present invention will become better understood with regard to the following description, appended claims, and accompanying drawings, where:

FIG. 1 is simplified block diagram showing a CMOS image sensor device;

FIG. 2 is simplified cross-sectional side view showing a portion of the CMOS image sensor of FIG. 1; and

FIG. 3 is a cross-sectional side view showing an inter-metal dielectric utilized in the CMOS image sensor of FIGS. 1 and 2.

### DETAILED DESCRIPTION OF THE DRAWINGS

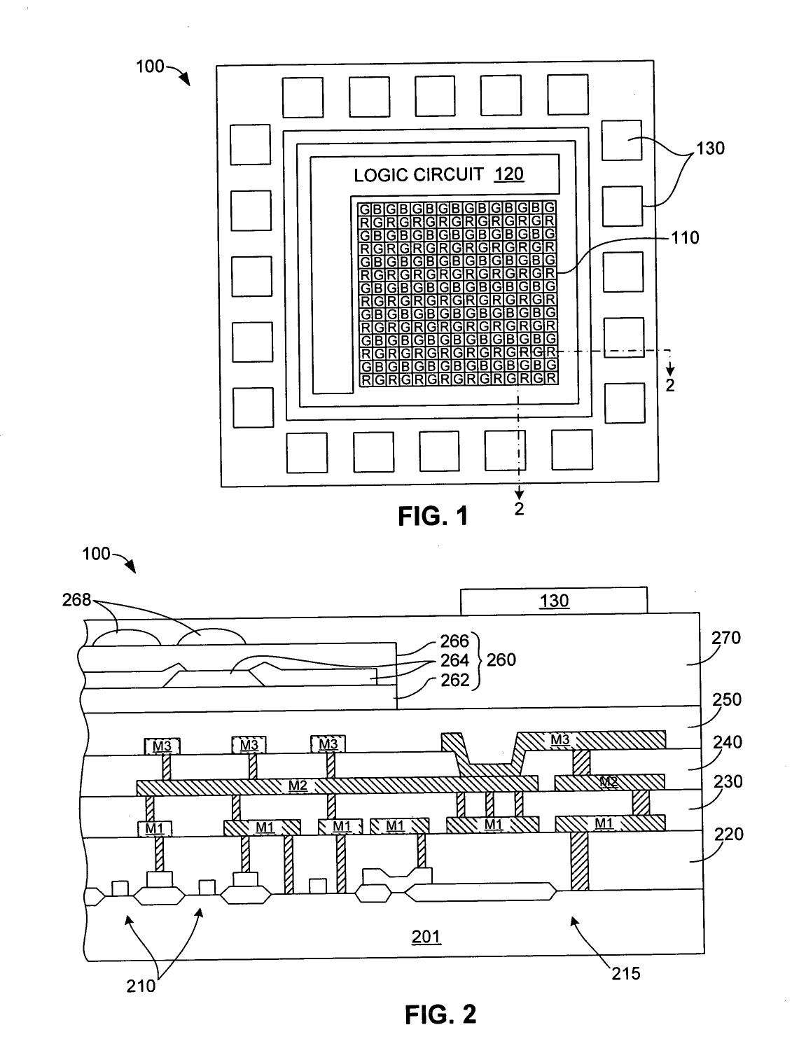

The present invention is directed to method to deposit an improved, spot-free dielectric stack that is utilized in place of the inter-metal dielectric layers of CMOS image sensor 100 shown in FIGS. 1-3. While the present invention is particularly useful in the production of image sensors, aspects of the present invention may be utilized in the fabrication of IC devices other than CMOS image sensors. Therefore, the present invention is limited only by the specific terms recited in the appended claims.

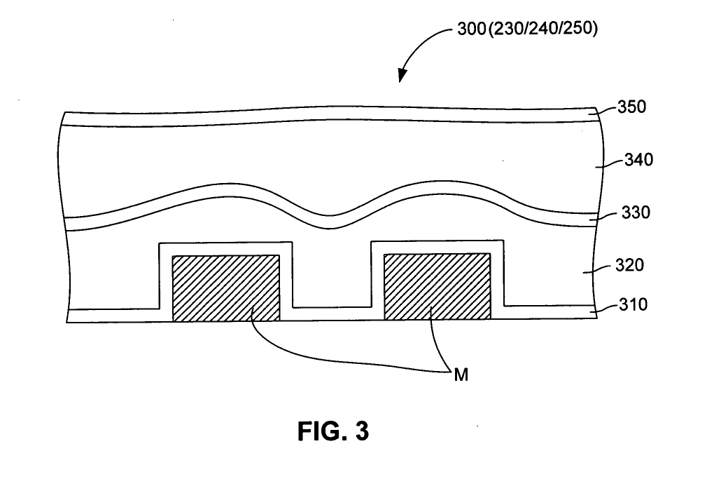

As mentioned above, the present inventors determined that the occurrence of the “rain drop” phenomenon described above result from the non-optimal conventional processing conditions used to produce inter-metal dielectric stack 300 (FIG. 3). In particular, the present inventors visually observed spots in flowlayers 320 and 340 of the various dielectric stacks 300. Accordingly, the present inventors experimented with various process parameters associated with the formation of flowlayers in an effort to reduce the occurrence of these spots. The base and cap layers of dielectric stack 300 are produced in accordance with the process parameters described in U.S. Pat. No. 5,891,800.

Briefly described, the flowlayer formation process includes four steps: a cooling step, a peroxide stabilization step, a flowlayer deposition step, and an H₂O₂ stabilization step. Through experimentation with the process parameters associated with the conventional flowlayer formation process, the present inventors identified three process parameters as having an effect on the production of these spots: H₂O₂ stabilization time, flowlayer deposition pressure, and the temperature of the reaction chamber platen. In particular, the present inventors found that decreasing the flowlayer deposition pressure, increasing the platen temperature, and shortening the H₂O₂ stabilization step, were shown to reduce the size and amount of the “rain drop” producing spots formed on the resulting. Each of these process modifications is discussed in additional detail below.

H₂O₂ Stabilization

The H₂O₂ stabilization step is used in conventional flowlayer formation processes to answer the need for improved global planarity requirement brought about by the design of advanced CMOS products. Such planarity is needed to allow photolithography of subsequent layers to the dielectric stack to take place successfully for high and low topography structures/locations on the wafer. When the H₂O₂ stabilization step was developed, a range of 50 to 100 seconds of H₂O₂ stabilization step was added with no adverse results.

By way of explanation, the need for the H₂O₂ stabilization step has to do with the narrow process window of the flowlayer formation process. This narrow window emanates from the phase diagram of water related to the low pressure and temperature (approaching 0° C.) prevailing in the reaction chamber, and the fragile equilibrium of peroxide-water involved in the polymerization of Silicic acid, which is the transient product of the flowlayer. This Silicic acid is responsible for the gap filling and planarization properties of the flowlayer.

The present inventors found that longer H₂O₂ stabilization times encouraged the appearance and severity of the spots that produced the “rain drops” phenomenon. These longer H₂O₂ stabilization times (i.e., between approximately 55 and 100 seconds) promoted condensation upon the wafer, which resulted in appearance of spots. Shorter H₂O₂ stabilization times (e.g., 0 to 30 seconds) discouraged this condensation phenomenon, but impaired global planarity requested by the photolithographic process. The inventors found that 30 to approximately 50 seconds, and most preferably approximately 50 seconds, provided an optimal H₂O₂ stabilization time, particularly when used in conjunction with the other parameters set forth below. Experimental results showed that times not exceeding approximately 50 seconds of H₂O₂ stabilization resulted in CMOS image sensor devices that were free of these spots. Therefore, in accordance with a first aspect of the present invention, an H₂O₂ stabilization step is utilized that is approximately 50 seconds.

Deposition Pressure

The feasible reaction chamber pressures for conventional flowlayer formation processes range from 400 to 1500 mTorr. However, the present inventors found that reaction chamber pressures at the higher and lower portions of this feasible range during the flowlayer deposition step encouraged the appearance and severity of the spots that produced the “rain drops” phenomenon. Specifically, the present inventors found that chamber pressures greater than approximately 850 mTorr resulted in appearance of spots, with the severity of the spots increasing as the pressure increased. Similarly, the inventors found that chamber pressures in the range of approximately 600 to 850 mTorr also produced spots, although less pronounced than those produced at higher pressures. The inventors found that reaction chamber pressures in the range of 400 to approximately 600 mTorr, and most preferably approximately 500 mTorr, provided optimal flowlayer deposition conditions, particularly when used in conjunction with the other process parameters set forth below. Experimental results showed that a reaction chamber pressure maintained at approximately 500 mTorr during the flowlayer deposition step resulted in CMOS image sensor devices that were free of these spots. Therefore, in accordance with a second aspect of the present invention, a flowlayer deposition step is performed in a reaction chamber maintained at approximately 500 mTorr.

Platen Temperature

During the flowlayer formation process, the wafer (substrate) is supported by a platen that is located in the reaction chamber. The temperature of this platen is conventionally set close to 0° C. However, the present inventors determined that the recommended platen temperature of 0° C. contributes to the formation of spots/rain drops, and experimented with platen temperatures above and below 0° C. In addition to the modified process parameters described above, the present inventors found that increasing the platen temperature above the recommended 0° C. throughout the flowlayer formation process further contributed to the reduction/elimination of spots. In particular, the present inventors determined that the optimal platen temperature range is greater than or equal to approximately 0.5° C. and less than or equal to approximately 3° C., with preferred target temperature of 1° C., particularly when used in conjunction with the other process parameters set forth below. Experimental results showed that a platen temperature maintained at 1° C. during the flowlayer deposition step resulted in CMOS image sensor devices that were free of these spots. Therefore, in accordance with a third aspect of the present invention, a flowlayer deposition step is performed with the wafer (substrate) supported on a platen maintained at approximately 1° C.

Experimental Results

CMOS image sensors produced using a Planar 200 unit produced by Trikon Technologies, Inc. of Newport, UK according to the modified process parameters set forth above verified disappearance of the “rain drops” phenomenon. In particular, CMOS image sensors similar to those shown in FIGS. 1 and 2 were produced with inter-metal layers formed in accordance with the dielectric stack 300 shown in FIG. 3, and having layer and overall stack thicknesses in the range set forth in Table 1 (below):

TABLE 1
Thickness Ranges for Dielectric Stack

| | LOW SPEC | | HIGH SPEC |
|---|---|---|---|
| LAYER | LIMIT (A) | TARGET (A) | LIMIT (A) |
| BASE LAYER 310 | 1,900 | 2,000 | 2,100 |
| FLOWLAYER 320 | 3,500 | 4,000 | 4,500 |
| CAP LAYER 330 | 1,425 | 1,500 | 1,575 |
| FLOWLAYER 340 | 5,500 | 6,000 | 6,500 |
| CAP LAYER 350 | 2,375 | 2,500 | 2,625 |
| STACK | 13,500 | 15,250 | 17,000 |

Note that the overall stack thickness does not match the algebraic sum of its component layer thicknesses in Table 1, since the thermal budget of individual tests is not identical to the overall thermal budget of the stack (flowlayers shrink during stack creation). Note also that following the production of the dielectric stack there is a baking process (i.e., 30 minutes at 400° C.).

During the flowlayer formation processes used to form flowlayers 320 and 340, the following global settings and process parameters set forth in Tables 2 and 3 (below) were utilized to produce the spot-free image sensors. It will be apparent, to one ordinarily skilled in the art, how to adapt these settings parameter values for other applications.

TABLE 2
Global Setting for Flowfill Layer

| | |
|---|---|
| NUMBER OF STEPS | 4 |
| TOTAL PROCESS TIME | AUTOMATIC |
| RECIPE TYPE | PROCESS |
| GAS TYPE | RED |
| GAS STAB. TIME | 30 |
| WARNING % | 85 |

TABLE 3
RECIPE For Second Flowfill Layer

| Step number | 1 | | 2 | | 3 | | 4 | |
|---|---|---|---|---|---|---|---|---|
| Step name | COOL | | LXO STABIL | | DEPOSITION | | H₂0₂ STABIL | |
| Valve group | Process | | Process | | Process | | Process | |
| Process Pressure (mT) | 1500 | 40% | 850 | 30% | 500 | 30% | 1400-1800 | 30% |
| APC angle (Deg) | 0.0 | | 0.0 | | 0.0 | | 0.0 | |
| APC mode | AUTOMATIC | | AUTOMATIC | | AUTOMATIC | | AUTOMATIC | |
| NITROGEN | 425 | 10% | 205 | 10% | 150 | 10% | 150 | 10% |
| NITROGEN | 0 | 5% | 0 | 5% | 0 | 5% | 0 | 5% |
| FREON 14 | 0 | 5% | 0 | 5% | 0 | 5% | 0 | 5% |
| NITROGEN | 0 | 5% | 0 | 5% | 0 | 5% | 0 | 5% |
| NITROGEN | 0 | 5% | 0 | 5% | 0 | 5% | 0 | 5% |
| SILANE | 0 | 5% | 0 | 5% | 120 | 10% | 0 | 5% |
| NITROGEN | 425 | 10% | 205 | 10% | 150 | 10% | 150 | 10% |
| Process time (Sec) | 25 | | 10 | | ** | | 50 | |
| RF load power | 0 | 5% | 0 | 5% | 0 | 5% | 0 | 10% |
| Matching unit range | | 4 | | 4 | | 4 | | 4 |
| LXO rate | 0.65 | 99% | 0.65 | 30% | 0.65 | 10% | 0.65 | 10% |
| Deposition (Micron) | 0.00 | | 0.00 | | 0.60 | | 0.00 | |

In table 2, the “red” gas type indicates that, along with the Silane allowed to flow into the reaction chamber, only N₂, and N₂O gases are allowed in the chamber (i.e., Oxygen is forbidden) to prevent the mix of Silane and Peroxide at temperatures above 0° C., which may lead to an explosion. The gas stabilization time is the time allowed at the beginning of each step for the MFC (Flow Control unit) to stabilize gas flow. During this period, gas flow tolerance checking does not take place. Accordingly, on top of the 25 seconds process time mentioned in the COOL step (no.1) of the flowlayer formation process (shown in Table 3), an additional 30 seconds are required. Finally, “Warning %” is the percentage of the tolerance of a step parameter at which a warning will be generated. For example, if a gas flow tolerance is 5% and the warning percentage is 80%, then a warning will be generated when the gas flow is outside the 4% tolerance band.

In Table 3, the “APC angle” and “APC mode” refer to an APC vane of the Planar 200, which governs the flow of gases out of the reaction chamber by obstructing gas flow. In manual mode, the angle range is from 0° (fully open) to 90° (fully closed). In automatic mode (which is the case in the flowlayer recipe shown in Table 3) an angle of 0° indicates pressure control maintains the angle.

Also, there are two lines in the Planar 200 that can flow Nitrogen gas into the reaction chamber. Nitrogen acts as a diluent to the H₂O₂ gas. The utilization of more than one line smoothes fluctuations in the Peroxide (LXO) flow, which in its turn stabilizes the deposition rate of the flowlayer. Thus, a more stable H₂O₂ supply rate and deposition rate results.

Also in Table 3, the “XXX X %” format in the gas fields (e.g., Nitrogen) indicates the gas flow rate (in standard cubic centimeters per minute (sccm)) followed by the percent error that will produce a fault indication on the module control page (e.g. yellow alarm). For gases with zero flow the default level written by the software is 5%, even though it is meaningless, since there is no gas flow to measure its fluctuation. The “Matching unit range” refers to a serial number of a coil activated in the specific chamber to bring the reflected RF power in the chamber to zero. For each chamber based on trial and error tests, a different coil (one of five available coils) may control impedance to bring about reflected power to zero when RF is turned on. That assures best plasma effect. In the flowlayer reaction chamber there is plasma only in clean process in between processed wafers. Therefore again the zero and percent tolerance near it in the “RF load power” is software-generated item without any meaning to the actual deposition process.

Near the bottom of Table 3, “LXO rate” refers to the peroxide flow rate. In the reaction chamber of the Planar 200, liquid concentrated peroxide is fed from a container called “Pot” to a unit called “Flasher”, which evaporates the peroxide and flows it as gas to the chamber. The quantity of peroxide gas supplied to the chamber is determined through a balance on which the Pot is positioned. The units of peroxide supply are grams/minute. Finally, “Process time” refers to a deposition time range for the layer involved. It has a process window based on the resultant thickness. The recipe shown in Table 3 does not have a number since based on daily tests and platen temperature the deposition rate may vary slightly, and hence the time needed for a certain thickness is varying. When actual wafers are processed in the machine, the process time is entered into step 3 (e.g., 48 to 56 seconds, depending upon the deposition rate of the Planar 200 unit).

The inventors note that the three modified process parameters identified above provide an improved flowlayer formation process. However, due to experimental constraints, the effect of these modified process parameters under all possible combinations of process parameter variations is not feasible. Yet, in view of the complexity of the flowlayer formation process, the fact that the process is based on water transition between states (rather than space continuity assumed in the statistical approach used to identify the three parameters), and the narrow process window of the associated reaction, the inventors determined that the three identified parameters set forth above provide a greatly improved flowlayer formation process for rain drops free products under most processing conditions.

Although the present invention has been described with respect to certain specific embodiments, it will be clear to those skilled in the art that the inventive features of the present invention are applicable to other embodiments as well, all of which are intended to fall within the scope of the present invention.

1. A method for forming a transparent inter-metal dielectric in a CMOS image sensor comprising:
forming a base SiO₂ layer,
forming a flowlayer on the base SiO₂ layer by reacting SiH₄ and H₂O₂, and
forming a cap SiO₂ layer on the flowlayer,
wherein forming the flowlayer includes using a shortened H₂O₂ stabilization time in the range of 30 seconds to approximately 50 seconds.

2. The method according to claim 1, wherein the shortened H₂O₂ stabilization time is approximately 50 seconds.

3. The method according to claim 1, wherein forming the flowlayer further comprises using an H₂O₂ deposition pressure in the range of 400 mTorr to approximately 600 mTorr.

4. The method according to claim 2, wherein forming the flowlayer further comprises using an H₂O₂ deposition pressure of approximately 500 mTorr.

5. The method according to claim 1, wherein forming the flowlayer further comprises maintaining the reaction chamber platen at a target value in the range of 0.5 to 3° C.

6. The method according to claim 2, wherein forming the flowlayer further comprises maintaining the reaction chamber platen at a target value of approximately 1° C.

7. The method according to claim 3, wherein forming the flowlayer further comprises maintaining the reaction chamber platen at a target value in the range of 0.5 to 3° C.

8. The method according to claim 3, wherein forming the flowlayer further comprises maintaining the reaction chamber platen at a target value of approximately 1° C.

9. A method for forming a transparent inter-metal dielectric in a CMOS image sensor comprising:
forming a base SiO₂ layer,
forming a flowlayer on the base SiO₂ layer by reacting SiH₄ and H₂O₂, and
forming a cap SiO₂ layer on the flowlayer,
wherein forming the flowlayer includes using an H₂O₂ deposition pressure in the range of 400 mTorr to approximately 600 mTorr.

10. The method according to claim 9, wherein the H₂O₂ deposition pressure is approximately 500 mTorr.

11. The method according to claim 9, wherein forming the flowlayer further comprises maintaining the reaction chamber platen at a target value in the range of 0.5 to 3° C.

12. The method according to claim 10, wherein forming the flowlayer further comprises maintaining the reaction chamber platen at a target value of approximately 1° C.

13. A method for forming a transparent inter-metal dielectric in a CMOS image sensor comprising:
mounting a substrate on a platen in a reaction chamber,
forming a base SiO₂ layer over the substrate,
forming a flowlayer on the base SiO₂ layer by reacting SiH₄ and H₂O₂, and
forming a cap SiO₂ layer on the flowlayer,
wherein forming the flowlayer includes maintaining the reaction chamber platen at a target value in the range of 0.5 to 3° C.

14. The method according to claim 3, wherein the target lue is approximately 1° C.
